(19) United States
(12) Patent Application Publication
(10) Pub. No.: US 2006/0202710 A1
(43) Pub. Date: Sep. 14, 2006

(54) Transmission line termination impedance compensation circuit

(76) Inventor: Peng-Fei Lin, Hsinchu Hsien (TW)

Correspondence Address: LIN & ASSOCIATES INTELLECTUAL PROPERTY, P.O. BOX 2339, SARATOGA, CA, 95070-0339, US

(21) Appl. No.: 11/078,924

(22) Filed: Mar. 12, 2005

(51) Int. Cl. H03K 19/003

(52) U.S. Cl. 326/30

(57) ABSTRACT

An on-chip termination impedance compensation circuit is provided. The termination impedance generated by the compensation circuit is precise and could absorb the impedance variances resulted from chip manufacturing process, temperature, and noise. The most significant feature of the compensation circuit is that the termination impedance is provided by a digitally calibrated resistor array composed of n+1 resistors in parallel, whose impedances are 2⁰×k×r, 2¹×k×r, 2²×k×r, . . . , 2ⁿ×k×r, respectively, where k, r are pre-determined values. By turning on or off each of the n+1 switch devices that are series-connected to the n+1 resistors respectively, the resistor array is able to provide a termination impedance that is k/m times of the external impedance to be compensated.

### BACKGROUND OF THE INVENTION

1. Field of the Invention

The present invention generally relates to transmission line termination impedance, and more particularly to a compensation circuit using digital calibration to provide termination impedance for compensating a transmission line.

2. The Prior Arts

In the past two decades, the raw computing power has grown exponentially and, along with the trend, the signal transmission speed between various computing devices has also reached GHz level. Under such a high speed, any signal transmission wire, such as a coaxial cable, a microstrip line, etc., could be considered equivalent to a transmission line having series-connected impedance and inductance components, and parallel-connected capacitance and conductance components.

When a signal transmitted at a high speed over a transmission line reaches and enters a terminal element (an IC such as a CPU, memory, etc.) at the end, the characteristic impedance of the transmission line has to be compatible with the input impedance of the terminal element, so that the reflection index would be zero and signal ringing and distortion could be avoided. Generally, in order to achieve the transmission line impedance compensation is to provide a termination resistor between the end of the transmission line and ground. As illustrate in FIG. 1, if the characteristic impedance Zo of a transmission line T is 28 ohm and the impedance Zt of a termination resistor R is also 28 ohm, then a signal S would undergo the minimum reflection and distortion, and the signal integrity would be effectively preserved even under a high-speed transmission. However, such an arrangement would allow only 50% power of the signal S to reach the end of the transmission line T. The impedance of the termination resistor R is therefore more carefully arranged in real-life applications so as to strike a balance among factors such as power loss and distortion.

Conventionally, the configuration of termination resistor could be categorized into two types: off-chip and on-chip (or on-die). Using off-chip termination resistors would usually increase the complexity of circuit board layout. Additionally, so-called impedance discontinuity where reflection usually occurs is also a frequent problem for off-chip termination resistors. In contrast, on-chip termination resistors generally offer better signal integrity and, therefore, are more suitable for high-speed applications. However, the impedance of on-chip termination resistors is usually varied under the influence of temperature, manufacturing process, and voltage (under the influence of noise). A conventional termination resistor made by CMOS process could have an impedance variance up to 30%. The key factor for using on-chip termination resistors, therefore, is to accurately calibrate the impedance of the on-chip termination resistors.

### SUMMARY OF THE INVENTION

The major objective of the present invention is to provide a termination impedance compensation circuit that can obviate the shortcomings of conventional on-chip termination resistors. In other words, the compensation circuit of the present invention could accommodate the variance of termination impedance resulted from changes in the temperature, manufacturing process, and voltage.

Another objective of the present invention is that the compensation circuit provided could offer termination impedance that is the same as the external impedance Rₑₓₜ (i.e., the characteristic impedance of the transmission line to be compensated), an integral multiple of Rₑₓₜ, or even Rₑₓₜ×k/m (k>0, m≧1). A chip designer is therefore given more freedom when trying to strike a balance between power loss and distortion.

The most significant feature of the compensation circuit provided by the present invention is that a resistor array composed of n+1 (n≧1) resistors in parallel are used to provide the termination impedance, and the termination impedance is digitally calibrated. The impedance of these n+1 resistors is 2⁰×k×r, 2¹×k×r, 2²×k×r, . . . , 2ⁿ×k×r, respectively, where k, r are pre-determined values. By turning on or off each of the n+1 switch devices that are series-connected to the n+1 resistors respectively, the resistor array is able to provide termination impedance Rₑₓₜ×k/m.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 is a schematic diagram showing the relationship between a transmission line and a termination resistor.

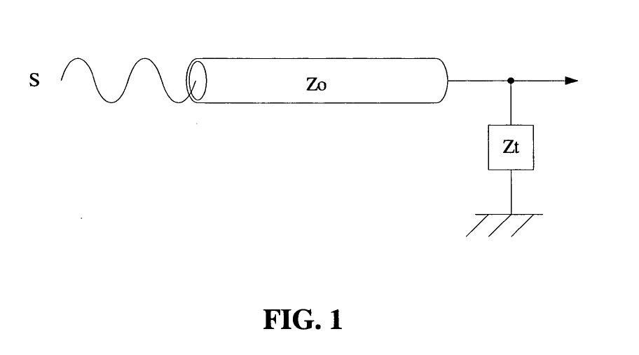

FIG. 2 is a schematic diagram showing an embodiment of the termination resistor array according to the present invention.

FIG. 3 is a schematic diagram showing an embodiment of the calibration circuit according to the present invention.

### DETAILED DESCRIPTION OF THE PREFERRED EMBODIMENTS

In the following, detailed description along with the accompanied drawings is given to better explain preferred embodiments of the present invention.

The termination impedance compensation circuit of the present invention is implemented inside a chip to provide a termination impedance to compensate a high-speed I/O transmission line outside the chip. The compensation circuit mainly contains a calibration circuit and a termination resistor array.

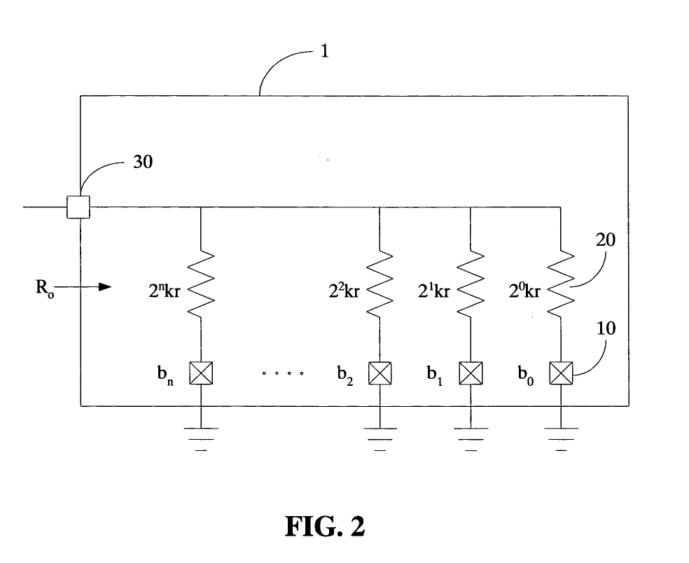

FIG. 2 is a schematic diagram showing an embodiment of the termination resistor array according to the present invention. As illustrated, inside a chip 1, the termination resistor array contains n+1 (n≧1) resistors 20 in parallel connection, whose impedance is 2⁰×k×r, 2¹×k×r, 2²×k×r, . . . , 2ⁿ×k×r, respectively (k, r>0). The n+1 resistors 20 are arranged sequentially according to their impedance values, and each of which is series-connected to a switch device 10 respectively. These n+1 switch devices 10 could be implemented using PMOS or NMOS, and whose short-circuit or open-circuit state is determined by the control signals b₀, b₁, b₂, . . . , bₙ, respectively. Based on the control signals, the termination resistor array would show various impedances Rₒ when viewed from outside of the chip 1 into the contact pad 30. The contact pad 30 is where the transmission line (not numbered) connects to the chip 1.

Please note that the control signals b₀, b₁, b₂, . . . , bₙ are generated by the calibration circuit (not shown in FIG. 2). In other words, the state of each switch device 10 is under the control of the calibration circuit. For example, if the output of the calibration circuit is such that the switch devices 10 controlled by b₀ is short-circuited, b₁ is open-circuited, b₂ is open-circuited, and b₃˜bₙ are all short-circuited, the termination impedance Rₒ would be result of parallel connecting n−1 resistors 2⁰×k×r, 2³×k×r, 2⁴×k×r, . . ., 2ⁿ×k×r. In the following, the calibration circuit would be explained in details to show that Rₒ and Rₑₓₜ would have the following relationship according to the present invention:
Rₒ=Rₑₓₜ×k/m
where m (m≧1), k are all pre-determined parameters. With careful choice of the parameter values, the termination impedance delivered by the compensation circuit of the present invention could be flexibly changed according to the designer's requirement. The termination impedance could be Rₑₓₜ (when k/m=1), an integral multiple of Rₑₓₜ (when k/m is an integer), or Rₑₓₜ×k/m. A chip designer therefore has more freedom in balancing factors such as power loss and distortion.

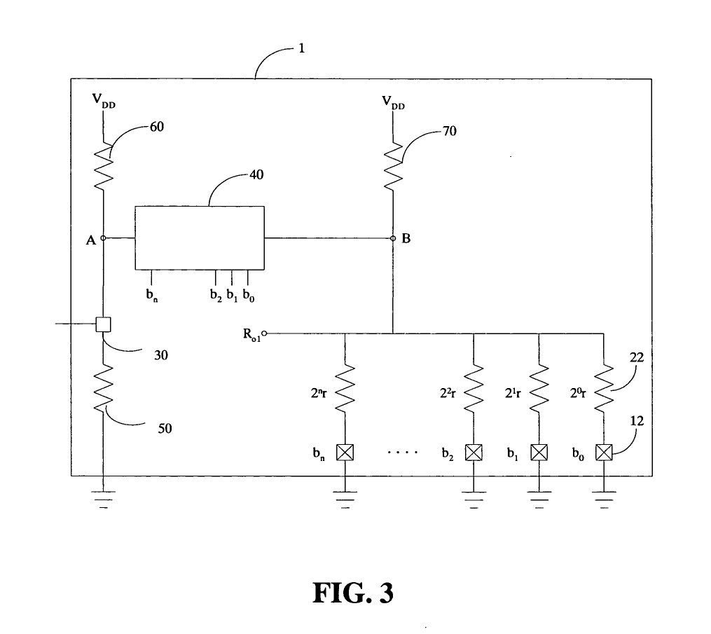

FIG. 3 is a schematic diagram showing an embodiment of the calibration circuit according to the present invention. As illustrated, the calibration circuit contains a comparison resistor array, structured identically to the termination resistor array shown in FIG. 2. The comparison resistor array also contains n+1 (n≧1) resistors 22 in parallel connection, whose impedances are 2⁰×r, 2¹×r, 2²×r, . . . , 2ⁿ×r, respectively, and each of which is also series-connected to a switch device 12 respectively. The states of the n+1 switch devices 12 and the n+1 switch devices 10 shown in FIG. 2 are all determined by the same control signals b₀, b₁, b₂, . . . , bₙ, respectively. Please note that the resistors 22 are arranged in the same sequential order as the resistors 20. Therefore, a control signal bⱼ (0≦j≦n) controls simultaneously the state of the switch device 10 series-connected to the resistor 2^{j}×k×r, and the state of the switch device 12 series-connected to the resistor 2^{j}×r. Rₒ₁ is the impedance manifested by the comparison resistor array.

The rest of the calibration circuit functions as a comparison circuit (not numbered). Within the comparison circuit, the comparator/counter device 40 takes the voltages at points A and B as input, and generates the control signals b₀, b₁, b₂, . . . , bₙ, that controls the switch devices 10 and 12 simultaneously, as output. Within the comparator/counter device 40, there is a counter (not shown) that would start counting from 0 when the voltages at points A and B are not equal to each other. The counter's value would be output by the comparator/counter device 40 in binary form as the control signals b₀, b₁, b₂, . . . , bₙ. In other words, when the voltages at points A and B are not equal to each other, the control signals b₀, b₁, b₂, . . . , bₙ from the comparator/counter device 40 would be sequentially changing in ascending order from 000 . . . 000, 000 . . . 001, 000 . . . 002, and so on. As mentioned earlier, the control signals b₀, b₁, b₂, . . . , bₙ would cause the switch devices 12 to be short-circuited or open-circuited and, thereby, alter the impedance Rₒ₁ of the comparison resistor array. The counter would continuously increase its value until the impedance Rₒ₁ has reached a certain level, causing the voltages at points A and B to become identical.

In the rest of the comparison circuit, the resistor 50 is configured to have impedance identical to the external impedance Rₑₓₜ to be compensated. The resistors 60 and 70 are configured such that the impedance of the resistor 70 is 1/m (m≧1) of the impedance of the resistor 60. With the foregoing counter operation and the configuration of the resistors 50, 60, and 70, when the voltages at points A and B are identical, the control signals b₀, b₁, b₂, . . . , bₙ would be driving the switch devices 12 so that:
R₀₁=Rₑₓₜ/m.
In addition, since the impedance of every resistor 20 in the termination resistor array is k times of the impedance of the corresponding resistor 22 in the comparison resistor array, and the two arrays share an identical set of control signals b₀, b₁, b₂, . . . , bₙ, it is therefore:
R₀=Rₑₓₜ×k/m.

There are various ways for implementing the comparison circuit. Foe example, the comparator/counter device 40 could use any appropriate counting circuit for its counter. The voltages comparison between points A and B could be conducted using differential amplifiers or similar techniques. All these should be quite intuitive for people of ordinary skill in the related arts and, therefore, no further details about the comparison circuit are given. The resistors 50, 60, and 70 could be implemented using PMOS or other methods.

In summary, the present embodiment utilizes the control signals b₀, b₁, b₂, . . . , bₙ to alter the impedance Rₒ₁ of the comparison resistor array, whose resistors 22 are arranged in a binary order in terms of their impedances, to approach Rₑₓₜ/m. Then the same set of control signals b₀, b₁, b₂, . . . , bₙ causes the similarly arranged termination resistor array to manifest an impedance Rₒ=Rₑₓₜ×k/m to compensate the external impedance Rₑₓₜ.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A transmission line termination impedance compensation circuit, said compensation circuit implemented inside a chip for generating a termination impedance to compensate an external impedance of a transmission line connected to said compensation circuit from outside of said chip, said compensation circuit comprising:
a termination resistor array generating said termination impedance; said termination resistor array composed of n+1 (n≧1) first resistors in parallel connection having impedances 2⁰×k×r, 2¹×k×r, 2²×k×r, . . . , 2ⁿ×k×r, respectively, said n+1 first resistors arranged in an ascending order according to their impedances, said n+1 first resistors series-connected to n+1 first switch devices respectively, each of said n+1 first switch devices having one of the two states consisting of an open-circuit state and a short-circuit state, said states of said n+1 first switch devices controlled by n+1 control signals b₀, b₁, b₂, . . . , bₙ respectively; and
a calibration circuit, said calibration circuit further comprising a comparison resistor array and a comparison circuit: said comparison circuit generating said n+1 control signals b₀, b₁, b₂, . . . , bₙ as output, said comparison resistor array composed of n+1 second resistors in parallel connection having impedances 2⁰×r, 2¹×r, 2²×r, . . . , 2ⁿ×r, respectively, said n+1 second resistors arranged in an ascending order according to their impedances and identical to the arrangement of said first resistors of said termination resistor array, said n+1 second resistors series-connected to n+1 second switch devices respectively, each of said n+1 second switch devices having one of the two states consisting of an open-circuit state and a short-circuit state, said states of said n+1 second switch devices controlled by said n+1 control signals b₀, b₁, b₂, . . . , bₙ respectively;
wherein a control signal bⱼ (0≦j≦n) generated by said comparison circuit determines simultaneously said state of a first switch device series-connected to a first resistor whose impedance is 2^{j}×k×r and said state of a second switch device series-connected to a second resistor whose impedance is 2^{j}×r, said comparison circuit automatically adjusts said n+1 control signals b₀, b₁, b₂, . . . , bₙ and their corresponding second switch devices are thereby set to a combination of said states until an impedance of said comparison resistor array is equal to 1/m of said external impedance, and the corresponding first switch devices are set to a combination of said states by said adjusted control signals b₀, b₁, b₂, . . . , bₙ such that said termination impedance of said termination resistor array is equal to k/m of said external impedance.

2. The transmission line termination impedance compensation circuit as claimed in claim 1, wherein said first switch device is formed using one of the two methods consisting of PMOS and NMOS.

3. The transmission line termination impedance compensation circuit as claimed in claim 1, wherein said second switch device is formed using one of the two methods consisting of PMOS and NMOS.
